(19) United States
(12) Patent Application Publication
(10) Pub. No.: US 2025/0056796 A1
(43) Pub. Date: Feb. 13, 2025

(54) MEMORY DEVICE AND METHOD OF MANUFACTURING THE MEMORY DEVICE

(71) Applicant: SK hynix Inc., Icheon-si Gyeonggi-do (KR)

(72) Inventors: Won Geun CHOI, Icheon-si Gyeonggi-do (KR); Jeong Hwan KIM, Icheon-si Gyeonggi-do (KR); Jung Shik JANG, Icheon-si Gyeonggi-do (KR)

(73) Assignee: SK hynix Inc., Icheon-si Gyeonggi-do (KR)

(21) Appl. No.: 18/519,680

(22) Filed: Nov. 27, 2023

(30) Foreign Application Priority Data
Aug. 10, 2023 (KR) 10-2023-0104732

(51) Int. Cl. H10B 43/27; G11C 16/08

(52) U.S. Cl. CPC H10B 43/27; G11C 16/08; G11C 16/0483

(57) ABSTRACT

The present technology includes a memory device and a method of manufacturing the memory device. The memory device includes a memory block in which first and second connection regions and a cell region between the first and second connection regions are designated, a word line included in the memory block, a first drain selection line included in the memory block and positioned on the word line, a first drain contact contacting the first drain selection line of the first connection region, a second drain contact contacting the first drain selection line of the second connection region, and a first drain voltage supply line commonly contacting the first and second drain contacts.

### CROSS-REFERENCE TO RELATED APPLICATION

The present application claims priority under 35 U.S.C. § 119 (a) to Korean patent application number 10-2023-0104732 filed on Aug. 10, 2023, in the Korean Intellectual Property Office, the entire disclosure of which is incorporated by reference herein.

### BACKGROUND

### 1. Technical Field

The present disclosure generally relates to a memory device and a method of manufacturing the memory device, and more particularly, to a three-dimensional memory device and a method of manufacturing the three-dimensional memory device.

### 2. Related Art

A memory device may include a memory cell array in which data is stored, and peripheral circuits configured to perform a program, read, or erase operation of the memory cell array.

The memory cell array may include a plurality of memory blocks. The memory blocks may be formed in a three-dimensional structure. Different memory blocks may be divided from each other by slits.

A memory device formed in a three-dimensional structure may include peripheral circuits stacked on a substrate and memory blocks stacked on the peripheral circuits. Because the memory blocks are positioned above the peripheral circuits, the memory blocks may include a cell region in which memory cells capable of storing data are included and connection regions electrically connected to the peripheral circuits. The cell region may be positioned between connection regions.

The memory block includes a plurality of memory cells for high-capacity data storage capability. As the number of memory cells increases, a size of the memory blocks may increase, and thus a time required for operation voltages generated from the peripheral circuits to be transferred to the memory blocks may increase.

### SUMMARY

According to an embodiment of the present disclosure, a memory device includes a memory block in which first and second connection regions and a cell region between the first and second connection regions are designated, a word line included in the memory block, a first drain selection line included in the memory block and positioned on the word line, a first drain contact contacting the first drain selection line of the first connection region, a second drain contact contacting the first drain selection line of the second connection region, and a first drain voltage supply line commonly contacting the first and second drain contacts.

According to an embodiment of the present disclosure, a memory device includes first and second connection regions and a cell region between the first and second connection regions; a first drain selection line extended in a first direction to be located within the first and second connection regions and the cell region; a bit line positioned on the first drain selection line in the cell region; a first drain contact contacting the first drain selection line of the first connection region; a second drain contact contacting the first drain selection line of the second connection region; a first drain voltage supply line contacting the first drain contact; and a second drain voltage supply line contacting the second drain contact, wherein the first and second drain voltage supply lines and the bit line are positioned on the same plane.

According to an embodiment of the present disclosure, a memory device includes a voltage generator configured to output a drain voltage through a global line, a row decoder connected to the voltage generator through the global line and transferring the drain voltage to a drain voltage supply line, a drain selection line connected to a memory block, and drain contacts connected to both ends of the drain selection line, and the drain contacts are commonly connected to the drain voltage supply line.

According to an embodiment of the present disclosure, a method of manufacturing a memory device includes forming a word line and a drain selection line positioned on the word line, in first and second connection regions and a cell region between the first and second connection regions, forming an interlayer insulating layer on the entire structure including the drain selection line, forming first and second drain contacts contacting the drain selection line positioned in the first and second connection regions, forming a word line contact contacting the word line positioned in the first connection region, and forming a drain voltage supply line contacting the first and second drain contacts on the first and second drain contacts and the first interlayer insulating layer.

According to an embodiment of the present disclosure, a method of manufacturing a memory device includes forming word lines, a first drain selection line positioned on the word lines, and a second drain selection line positioned on the first drain selection line, in first and second connection regions and a cell region between the first and second connection regions, forming an interlayer insulating layer in the entire structure including the second drain selection line, forming first and second drain contacts each contacting the first drain selection line in the first and second connection regions, forming third and fourth drain contacts each contacting the second drain selection line in the first and second connection regions, forming word line contacts respective contacting the word lines positioned in the first connection region, forming a first drain voltage supply line commonly contacting the first and second drain contacts, and forming a second drain voltage supply line commonly contacting the third and fourth drain contacts.

### BRIEF DESCRIPTION OF THE DRAWINGS

FIG. 1 is a diagram illustrating a memory device according to an embodiment of the present disclosure.

FIG. 2 is a perspective view illustrating the memory device.

FIG. 3 is a circuit diagram illustrating a connection structure of a memory device according to an embodiment of the present disclosure.

FIG. 4 is a perspective view illustrating a structure of a memory device according to a first embodiment of the present disclosure.

FIG. 5 is a cross-sectional view illustrating the structure of the memory device according to the first embodiment of the present disclosure.

FIG. 6 is a layout diagram illustrating the structure of the memory device according to the first embodiment of the present disclosure.

FIGS. 7A, 7B, 7C, 7D, 7E, 7F, 7G, 7H, 7I and 7J are diagrams illustrating a method of manufacturing the memory device according to the first embodiment of the present disclosure.

FIG. 8 is a layout diagram illustrating a structure of a memory device according to a second embodiment of the present disclosure.

FIG. 9 is a perspective view illustrating the structure of the memory device according to the second embodiment of the present disclosure.

FIG. 10 is a perspective view illustrating a structure of a memory device according to a third embodiment of the present disclosure.

FIG. 11 is a circuit diagram illustrating a connection structure of a memory device according to a fourth embodiment of the present disclosure.

FIG. 12 is a perspective view illustrating the structure of the memory device according to the fourth embodiment of the present disclosure.

FIG. 13 is a view illustrating a B1-B2 cross-section of the structure shown in FIG. 12.

FIG. 14 is a view illustrating a C1-C2 cross-section of the structure shown in FIG. 12.

FIG. 15 is a diagram illustrating an embodiment of a memory card system to which a memory device of the present disclosure is applied.

FIG. 16 is a diagram illustrating an embodiment of a solid state drive (SSD) system to which a memory device of the present disclosure is applied.

### DETAILED DESCRIPTION

Specific structural or functional descriptions of the embodiments according to the concept of the present disclosure disclosed in the present specification or application are exemplified for the purpose of describing the embodiment according to the concept of the present disclosure, and the embodiments according to the concept of the present disclosure may be embodied in various forms and should not be construed as limited to the embodiments described in the present specification or application. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly. It will be understood that although the terms first, second, third etc. may be used herein to describe various elements, these elements should not be limited by these terms. These terms are only used to distinguish one element from another element, but not used to define only the element itself or to mean a particular sequence.

An embodiment of the present disclosure provides a memory device and a method of operating the memory device capable of improving an operation speed of the memory device. According to an embodiment of the present technology, an operation speed of a memory device may be improved.

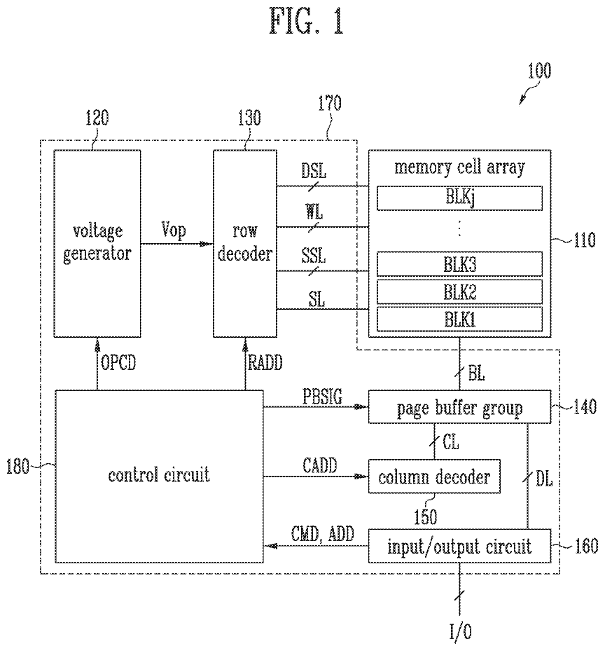

FIG. 1 is a diagram illustrating a memory device according to an embodiment of the present disclosure.

Referring to FIG. 1, the memory device 100 may include a memory cell array 110 and a peripheral circuit 170.

The memory cell array 110 may include first to j-th memory blocks BLK1 to BLKj. Each of the first to j-th memory blocks BLK1 to BLKj may include memory cells capable of storing data. The memory blocks may be formed in a three-dimensional structure. Drain selection lines DSL, word lines WL, source selection lines SSL, and a source line SL may be connected to each of the first to j-th memory blocks BLK1 to BLKj, and a bit line BL may be commonly connected to the first to j-th memory blocks BLK1 to BLKj. In an embodiment, j may be a natural number greater than one.

The first to j-th memory blocks BLK1 to BLKj may be formed in a two-dimensional structure or a three-dimensional structure. The memory blocks having the two-dimensional structure may include memory cells arranged parallel to a substrate. The memory blocks having a three-dimensional structure may include memory cells stacked on a substrate in a vertical direction. Memory blocks formed in a three-dimensional structure are disclosed in the present embodiment.

The memory cells may store 1 bit or 2 bits or more of data according to a program method. For example, a method in which 1 bit of data is stored in one memory cell is referred to as a single level cell method, and a method in which 2 bits of data is stored in one memory cell is referred to as a multi-level cell method. A method in which 3 bits of data is stored in one memory cell is referred to as a triple level cell method, and a method in which 4 bits of data is stored in one memory cell is referred to as a quad level cell method. In addition to this, five bits or more of data may be stored in one memory cell.

The peripheral circuit 170 may be configured to perform the program operation of storing data in the memory cell array 110, the read operation of outputting the data stored in the memory cell array 110, and the erase operation of erasing the data stored in the memory cell array 110. For example, the peripheral circuit 170 may include a voltage generator 120, a row decoder 130, a page buffer group 140, a column decoder 150, an input/output circuit 160, and a control circuit 180.

The voltage generator 120 may generate various operation voltages Vop used for the program operation, the read operation, or the erase operation in response to an operation code OPCD. For example, the voltage generator 120 may be configured to generate program voltages, turn-on voltages, turn-off voltages, negative voltages, precharge voltages, verify voltages, read voltages, pass voltages, or erase voltages in response to the operation code OPCD. The operation voltages Vop generated by the voltage generator 120 may be applied to the drain selection lines DSL, the word lines WL, the source selection lines SSL, and the source line SL of memory block selected through the row decoder 130.

The program voltages may be voltages applied to a selected word line among the word lines WL during the program operation, and may be used to increase a threshold voltage of memory cells connected to the selected word line. The turn-on voltages may be applied to the drain selection lines DSL or the source selection lines SSL, and may be used to turn on drain selection transistors or source selection transistors. The turn-off voltages may be applied to the drain selection lines DSL or the source selection lines SSL, and may be used to turn off the drain selection transistors or the source selection transistors. For example, the turn-off voltage may be set to OV. The precharge voltages may be a voltage higher than OV, and may be applied to bit lines during the read operation. The verify voltages may be used during a verify operation for determining whether a threshold voltage of selected memory cells is increased to a target level. The verify voltages may be set to various levels according to the target level, and may be applied to the selected word line.

The read voltages may be applied to the selected word line during the read operation of the selected memory cells. For example, the read voltages may be set to various levels according to a program method of the selected memory cells. The pass voltages may be voltages applied to unselected word lines among the word lines WL during the program or read operation, and may be used to turn on memory cells connected to the unselected word lines.

The erase voltages may be used during the erase operation for erasing memory cells included in the selected memory block, and may be applied to the source line SL.

The row decoder 130 may be configured to transmit the operation voltages Vop to the drain selection lines DSL, the word lines WL, the source selection lines SSL, and the source line SL connected to the selected memory block according to a row address RADD. For example, the row decoder 130 may be connected to the voltage generator 120 through global lines, and may be connected to the first to j-th memory blocks BLK1 to BLKj through the drain selection lines DSL, the word lines WL, the source selection lines SSL, and the source line SL.

The page buffer group 140 may include page buffers PB1 to PBn (not shown) connected to the first to j-th memory blocks BLK1 to BLKj. Each of the page buffers (not shown) may be connected to the first to j-th memory blocks BLK1 to BLKj through the bit lines BL. During the read operation, the page buffers (not shown) may sense a current or a voltage of the bit lines which varies according to threshold voltages of the selected memory cells, and store the sensed data, in response to page buffer control signals PBSIG. In an embodiment, n may be a natural number greater than one.

The column decoder 150 may be configured so that data is transmitted between the page buffer group 140 and the input/output circuit 160 in response to a column address CADD. For example, the column decoder 150 may be connected to the page buffer group 140 through column lines CL and may transmit enable signals through the column lines CL. The page buffers (not shown) included in the page buffer group 140 may receive or output the data through data lines DL in response to the enable signals.

The input/output circuit 160 may be configured to receive or output a command CMD, an address ADD, or data through input/output lines I/O. For example, the input/output circuit 160 may transmit the command CMD and the address ADD received from an external controller to the control circuit 180 through the input/output lines I/O, and transmit the data received from the external controller to the page buffer group 140 through the input/output lines I/O. Alternatively, the input/output circuit 160 may output the data received from the page buffer group 140 to the external controller through the input/output lines I/O.

The control circuit 180 may output the operation code OPCD, the row address RADD, the page buffer control signals PBSIG, and the column address CADD in response to the command CMD and the address ADD. For example, when the command CMD input to the control circuit 180 is a command corresponding to the program operation, the control circuit 180 may control devices included in the peripheral circuit 170 to perform the program operation of a memory block selected by the address ADD. When the command CMD input to the control circuit 180 is a command corresponding to the read operation, the control circuit 180 may control the devices included in the peripheral circuit 170 to perform the read operation of the memory block selected by the address and output the read data. When the command CMD input to the control circuit 180 is a command corresponding to the erase operation, the control circuit 180 may control the devices included in the peripheral circuit 170 to perform the erase operation of the selected memory block.

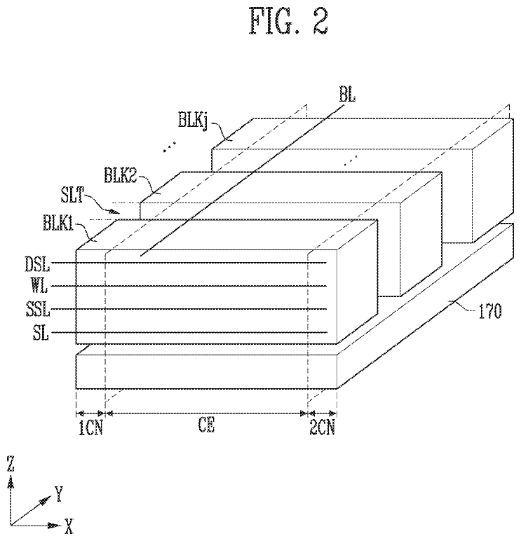

FIG. 2 is a perspective view illustrating the memory device.

Referring to FIG. 2, the first to j-th memory blocks BLK1 to BLKj included in the memory cell array may be positioned on the peripheral circuit 170. For example, the peripheral circuit 170 may be stacked on a substrate (not shown), and the first to j-th memory blocks BLK1 to BLKj may be stacked on the peripheral circuit 170.

Each of the first to j-th memory blocks BLK1 to BLKj positioned on the peripheral circuit 170 may extend along an X direction and may be spaced apart from each other along a Y direction. The first to j-th memory blocks BLK1 to BLKj may be divided from each other by a slit extending along the X direction. Each of the first to j-th memory blocks BLK1 to BLKj may include a source line SL, at least one source selection line SSL, at least one word line WL, and at least one drain selection line DSL. Each of the first to j-th memory blocks BLK1 to BLKj may include at least one source selection transistor, at least one memory cell, and at least one drain selection transistor. The source selection transistor may be connected to the source selection line, the memory cell may be connected to the word line, and the drain selection transistor may be connected to the drain selection line. The first to j-th memory blocks BLK1 to BLKj may share at least one bit line BL. The source selection transistor may be configured to electrically turn on or turn off between the source line and the memory cell. The memory cell may be configured to store data. The drain selection transistor may be configured to electrically turn on or turn off the memory cell and the bit line BL.

The first to j-th memory blocks BLK1 to BLKj may include a cell region CE configured to store data and first and second connection regions 1CN and 2CN configured to be connected to the peripheral circuit 170. The cell region CE may be positioned between the first connection region 1CN and the second connection region 2CN. The source selection transistor, the memory cell, and the drain selection transistor may be positioned in the cell region CE. Contacts configured to electrically connect the source selection line, the word line, and the drain selection line to the peripheral circuit 170 may be positioned in the first and second connection regions 1CN and 2CN.

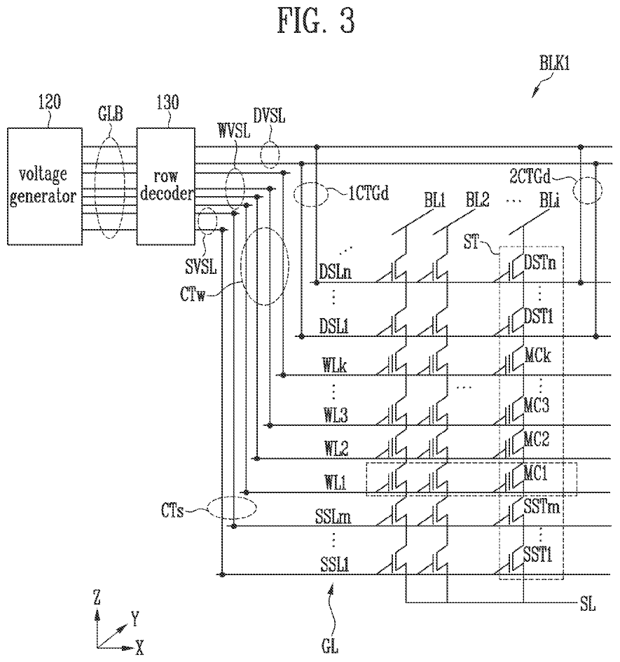

FIG. 3 is a circuit diagram illustrating a connection structure of a memory device according to an embodiment of the present disclosure.

Referring to FIG. 3, among the first to j-th memory blocks BLK1 to BLKj shown in FIG. 1, the first memory block BLK1 is shown as an example, and the remaining second to j-th memory blocks BLK2 to BLKj may also be configured similarly to the first memory block BLK1.

The voltage generator 120 may generate the operation voltages and transmit the operation voltages to the row decoder 130 through global lines GLB. The row decoder 130 may transmit the operation voltages to the memory block selected in response to the row address. For example, when the row address corresponds to the first memory block BLK1, the row decoder 130 may transmit the operation voltage to gate lines GL connected to the first memory block BLK1. The gate lines GL may include first to m-th source selection lines SSM1 to SSMm, first to k-th word lines WL1 to WLk, and first to n-th drain selection lines DSL1 to DSLn. Although not shown in the drawings, the gate lines GL may further include dummy lines. Among the memory blocks connected to the row decoder 130, gate lines of unselected memory blocks other than the selected memory block may be floating. In an embodiment, m may be a natural number greater than one. In an embodiment, k may be a natural number greater than one.

The first memory block BLK1 may include strings ST connected between the source line SL and first to i-th bit lines BL1 to BLi. The strings ST may be commonly connected to the source line SL, and may be connected to the first to i-th bit lines BL1 to BLi, respectively. The string ST may include first to m-th source selection transistors SST1 to SSTm, first to k-th memory cells MC1 to MCk, and first to n-th drain selection transistors DST1 to DSTn. Each of m, k, n, and i may be a positive integer and may vary according to the memory device. Gates of the first to m-th source selection transistors SST1 to SSTm may be connected to first to m-th source selection lines SSL1 to SSLm, gates of the first to k-th memory cells MC1 to MCk may be connected to first to k-th word lines WL1 to WLk, and the first to n-th drain selection transistors DST1 to DSTn may be connected to first to n-th drain selection lines DSL1 to DSLn. A group of memory cells connected to the same word line may configure a page PG, and a program or read operation may be performed in a unit of the page PG. In an embodiment, i may be a natural number greater than one.

In the drawing, although the first to m-th source selection transistors SST1 to SSTm, the first to k-th memory cells MC1 to MCk, and the first to n-th drain selection transistors DST1 to DSTn arranged along an XZ plane are shown, in the first memory block BLK1, the first to m-th source selection transistors SST1 to SSTm, the first to k-th memory cells MC1 to MCk, and the first to n-th drain selection transistors DST1 to DSTn arranged along the XZ plane may be further connected to the first to i-th bit lines BL1 to BLi along the Y direction. The strings ST may be selected by first to n-th drain selection transistors DST1 to DSTn connected along the Y direction. For example, the first to n-th drain selection transistors DST1 to DSTn arranged along a first XZ plane may be turned on, and the remaining first to n-th drain selection transistors DST1 to DSTn connected along the Y direction may be turned off.

A connection structure between the row decoder 130 and the first memory block BLK1 is specifically described as follows.

The first to m-th source selection lines SSL1 to SSLm of the first memory block BLK1 may be connected to the row decoder 130 through source contacts CTs and source voltage supply lines SVSL, and the first to k-th word lines WL1 to WLk may be connected to the row decoder 130 through word line contacts CTw and word line voltage supply lines WVSL. The first to n-th drain selection lines DSL1 to DSLn of the first memory block BLK1 may be connected to the row decoder 130 through a first drain contact group 1CTGd, a second drain contact group 2CTGd, and drain voltage supply lines DVSL.

A first drain contact group 1CTGd may be connected to one side of the first to n-th drain selection lines DSL1 to DSLn, and the second drain contact group 2CTGd may be connected to another side of the first to n-th drain selection lines DSL1 to DSLn. The first and second drain contact groups 1CTGd and 2CTGd may be commonly connected to the drain voltage supply lines DVSL.

For an embodiment, a reason why the first to n-th drain selection lines DSL1 to DSLn are connected to the drain voltage supply lines DVSL through the first and second drain contact groups 1CTGd and 2CTGd is for quickly connecting strings ST selected among the plurality of strings ST included in the first memory block BLK1 and the first to i-th bit lines BL1 to BLi.

When the second drain contact group 2CTGd does not exist, the first to n-th drain selection transistors DST1 to DSTn may be connected to the drain voltage supply lines DVSL through the first drain contact group 1CTGd. Therefore, when the operation voltage is output from the row decoder 130, the operation voltages may be sequentially supplied to the first to n-th drain selection transistors DST1 to DSTn through the drain voltage supply lines DVSL and the first drain contact group 1CTGd. Therefore, in an embodiment, the first bit line BL1 and the string ST may be connected the quickest, and the i-th bit line BLi and the strings ST may be connected the slowest. In an embodiment, as the number of bit lines increases, the slowest time at which a bit line and a string are connected may become even slower. That is, in an embodiment, a time difference between the fastest time and the slowest time at which the bit line and the string are electrically connected to each other may increase.

Therefore, in the present embodiment, in order to supply the operation voltages applied to the drain voltage supply lines DVSL through both ends of the first to n-th drain selection lines DSL1 to DSLn, the first and second drain contact groups 1CTGd and 2CTGd may be used. As described above, because the first drain contact group 1CTGd is connected to one side of the first to n-th drain selection lines DSL1 to DSLn, the second drain contact group 2CTGd is connected to the other side, and the first and second drain contact groups 1CTGd and 2CTGd are commonly connected to the drain voltage supply lines DVSL, the time difference at which the first to i-th bit lines BL1 to BLi and the strings ST are electrically connected may be reduced. In addition, in an embodiment, because contacts electrically connected between the first to n-th drain selection lines DSL1 to DSLn and the drain voltage supply lines DVSL increase, a resistance may decrease.

The word line contacts CTw are connected to one side of the first to k-th word lines WL1 to WLk, and the source contacts CTs are connected to one side of the first to m-th source selection lines SSL1 to SSLm, but contacts may also be connected to other sides of the first to k-th word lines WL1 to WLk and the first to m-th source selection lines SSL1 to SSLm, respectively. However, because a size of the memory device may increase in this case, in the present embodiment, the first drain contact group 1CTGd may be connected to one side of the first to n-th drain selection lines DSL1 to DSLn, and the second drain contact group 2CTGd may be connected to the other side of the first to n-th drain selection lines DSL1 to DSLn.

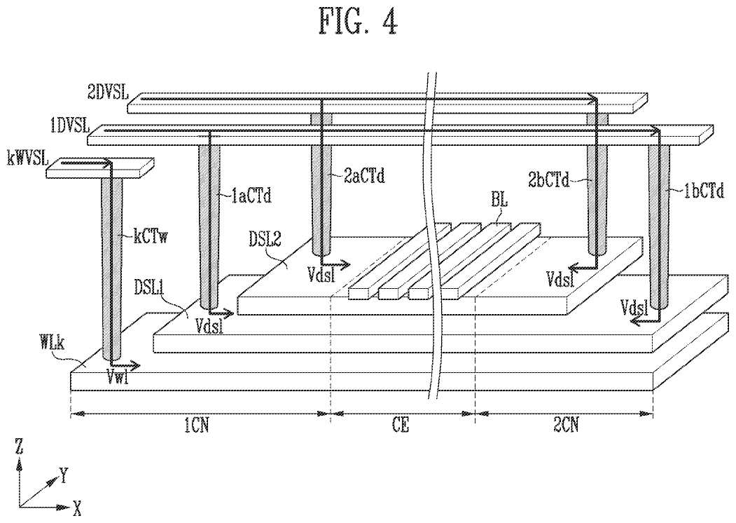

FIG. 4 is a perspective view illustrating a structure of a memory device according to a first embodiment of the present disclosure.

Referring to FIG. 4, a portion of a memory block in which first and second drain selection lines DSL and DSL2 are stacked is shown. In the first embodiment, a stack direction means a Z direction. The first drain selection line DSL1 may be positioned on the k-th word line WLk, and the second drain selection line DSL2 may be positioned on the first drain selection line DSL1. On the second drain selection line DSL2 of the cell region CE, bit lines BL may be spaced apart from each other along the X direction and arranged.

The cell region CE may be positioned between the first connection region 1CN and the second connection region 2CN, and it is assumed that a distance between the first connection region 1CN and the row decoder 130 of FIG. 3 is shorter than a distance between the second connection region 2CN and the row decoder 130 of FIG. 3.

The k-th word line WLk, the first word line DSL1, and the second word line DSL2 may have a step shape in the first connection region 1CN, and the k-th word line WLk, the first word line DSL1, and the second word line DSL2 may also have a step shape in the second connection region 2CN. In the first connection region 1CN, all gate lines including the k-th word line WLk, the first word line DSL1, and the second word line DSL2 may have a step shape. In the second connection region 2CN, only the first and second drain selection lines DSL1 and DSL2 may have a step shape, and remaining gate lines may be cut along the same YZ plane as the longest line in the X direction among the first and second drain selection lines DSL1 and DSL2. In the first and second connection regions 1CN and 2CN, the step shape has a shape in which a length of a step becomes narrower from a lower portion to an upper portion. Therefore, in the first and second connection regions 1CN and 2CN, an upper surface of the first drain selection line DSL1 positioned under the second drain selection line DSL2 may be exposed along the X direction. In the first connection region 1CN, the upper surface of the k-th word line WLk positioned under the first drain selection line DSL1 may be exposed along the X direction. In the second connection region 2CN, the upper surface of the k-th word line WLk positioned under the first drain selection line DSL1 might not be exposed.

A k-th word line contact kCTw may be positioned on the k-th word line WLk exposed in the first connection region 1CN, and a k-th word line voltage supply line kWVSL may be positioned on the k-th word line contact kCTw. The k-th word line voltage supply line kWVSL may be connected to the row decoder 130 of FIG. 3.

A 1a-th drain contact 1aCTd may be positioned on the first drain selection line DSL1 exposed in the first connection region 1CN, and a 1b-th drain contact 1bCTd may be positioned on the first drain selection line DSL1 exposed in the second connection region 2CN. A first drain voltage supply line 1DVSL may be positioned on the 1a-th and 1b-th drain contacts 1aCTd and 1bCTd. The first drain voltage supply line 1DVSL may be connected to the row decoder 130 of FIG. 3.

A 2a-th drain contact 2aCTd may be positioned on the second drain selection line DSL2 exposed in the first connection region 1CN, and a 2b-th drain contact 2bCTd may be positioned on the second drain selection line DSL2 exposed in the second connection region 2CN. A second drain voltage supply line 2DVSL may be positioned on the 2a-th and 2b-th drain contacts 2aCTd and 2bCTd. The second drain voltage supply line 2DVSL may be connected to the row decoder 130 of FIG. 3.

According to the above-described structure, a word line voltage Vwl output from the row decoder 130 of FIG. 3 may be applied to the k-th word line WLk through the k-th word line voltage supply line kWVSL and the k-th word line contact kCTw, and a drain voltage Vdsl output from the row decoder 130 of FIG. 3 may be applied to the first drain selection line DSL1 through the first drain voltage supply line 1DVSL, the 1a-th drain contact 1aCTd, and the 1b-th drain contact 1bCTd and may be applied to the second drain selection line DSL2 through the second drain voltage supply line 2DVSL, the 2a-th drain contact 2aCTd, and the 2b-th drain contact 2bCTd. The word line voltage Vwl may be a voltage applied to the word lines during the program, read, or erase operation. For example, the word line voltage Vwl may be a program voltage, a pass voltage, a verify voltage, or a ground voltage, and other various voltages that may be applied to the word lines. The drain voltage Vdsl may be a voltage for turning on or turning off the drain selection transistors during the program, read, or erase operation, and may be a positive voltage, a negative voltage, or a ground voltage.

As described above, voltages applied to gate lines other than the first and second drain selection lines DSL1 and DSL2 may be applied to the gate lines through the first connection region 1CN, respectively, and the drain voltage Vdsl applied to the first and second drain selection lines DSL1 and DSL2 may be applied to the first and second drain selection lines DSL1 and DSL2 through the first and second connection regions 1CN and 2CN, respectively.

Because, in an embodiment, the drain voltage Vdsl is applied through both ends of the first and second drain selection lines DSL1 and DSL2, a time required for the drain voltage Vdsl to be transferred to the drain selection transistors may be shortened.

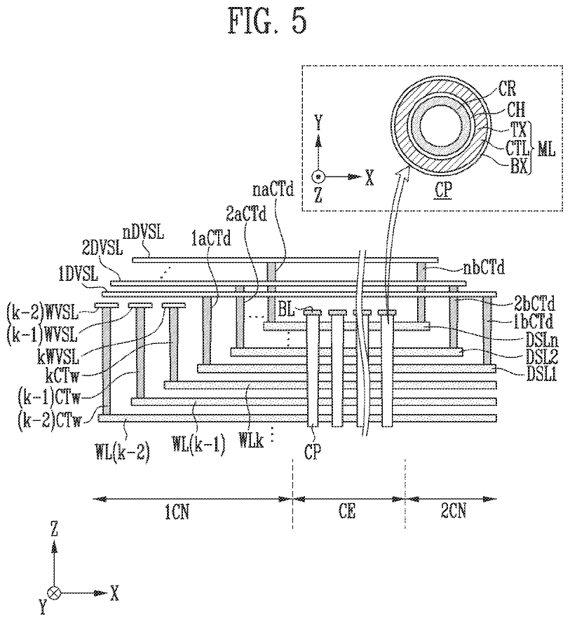

FIG. 5 is a cross-sectional view illustrating the structure of the memory device according to the first embodiment of the present disclosure.

Referring to FIG. 5, a cross-sectional view of the memory device taken along the XZ plane is shown. In FIG. 5, in order to describe a connection structure of 1a-th to na-th drain contacts 1aCTd to naCTd and first to n-th drain voltage supply lines 1DVSL to nDVSL, the first to n-th drain voltage supply lines 1DVSL to nDVSL are positioned on different layers, but substantially the first to n-th drain voltage supply lines 1DVSL to nDVSL may be arranged on the same layer. For example, the first to n-th drain voltage supply lines 1DVSL to nDVSL may be arranged on the same layer as (k−2)-th to k-th word line voltage supply lines (k−2) WVSL to kWVSL.

The cell region CE may include cell plugs CP extending in the Z direction and spaced apart from each other in the X and Y directions. Each of the cell plugs CP may include at least one source selection transistor, at least one memory cell, and at least one drain selection transistor. A structure of each of the cell plugs CP is described with reference to an XY plan view.

The cell plug CP may include a core pillar CR, a channel layer CH, and a memory layer ML. The memory layer ML includes a tunnel insulating layer (tunnel isolation layer) TX, a charge trap layer CTL, and a blocking layer BX. The core pillar CR may have a cylindrical shape and may be formed of an insulating material or a conductive material. The channel layer CH may have a cylindrical shape surrounding a side surface of the core pillar CR, and may be formed of polysilicon. The tunnel insulating layer TX may have a cylindrical shape surrounding a side surface of the channel layer CH and may be formed of an oxide layer. The charge trap layer CTL may have a cylindrical shape surrounding a side surface of the tunnel insulating layer TX and may be formed of a nitride layer. The blocking layer BX may have a cylindrical shape surrounding a side surface of the charge trap layer CTL and may be formed of an oxide layer.

(k−2)-th to k-th word lines WL (k−2) to WLk and the first to n-th drain selection lines DSL1 to DSLn of the first connection region 1CN may have a step shape. The (k−2)-th to k-th word lines WL (k−2) to WLk of the second connection region 2CN might not have a step shape, and the first to n-th drain selection lines DSL1 to DSLn may have a step shape.

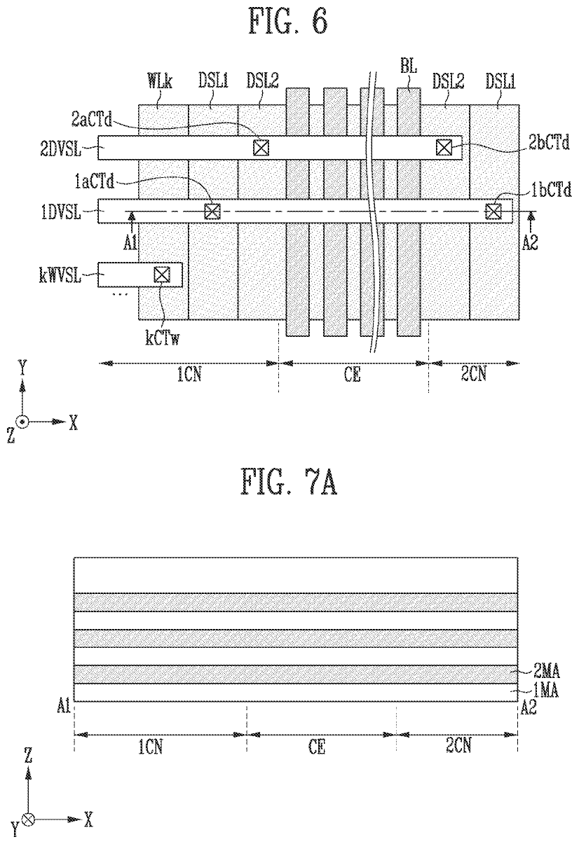

FIG. 6 is a layout diagram illustrating the structure of the memory device according to the first embodiment of the present disclosure.

Referring to FIG. 6, the bit lines BL may be arranged on the k-th word line WLk, the first drain selection line DSL1, and the second drain selection line DSL2 in the Z direction. The bit lines BL may extend along the Y direction and may be spaced apart from each other along the X direction. The k-th word line voltage supply line kWVSL, the first drain voltage supply line 1DVSL, and the second drain voltage supply line 2DVSL may be arranged on the bit lines BL in the Z direction. The k-th word line voltage supply line kWVSL, the first drain voltage supply line 1DVSL, and the second drain voltage supply line 2DVSL may extend along the X direction and may be spaced apart from each other along the Y direction.

The k-th word line voltage supply line kWVSL may be electrically connected to the k-th word line WLk through the k-th word line contact kCTw positioned in the first connection region 1CN. The first drain voltage supply line 1DVSL may be electrically connected to the first drain selection line DSL1 through the 1a-th drain contact 1aCTd positioned in the first connection region 1CN and the 1b-th drain contact 1bCTd positioned in the second connection region 2CN. The second drain voltage supply line 2DVSL may be electrically connected to the second drain selection line DSL2 through the 2a-th drain contact 2aCTd positioned in the first connection region 1CN and the 2b-th drain contact 2bCTd positioned in the second connection region 2CN. Therefore, in an embodiment, a length of the k-th word line voltage supply line kWVSL may be the shortest, a length of the second drain voltage supply line 2DVSL may be longer than the length of the k-th word line voltage supply line kWVSL, and a length of the first drain voltage supply line 1DVSL may be longer than the length of the second drain voltage supply line 2DVSL.

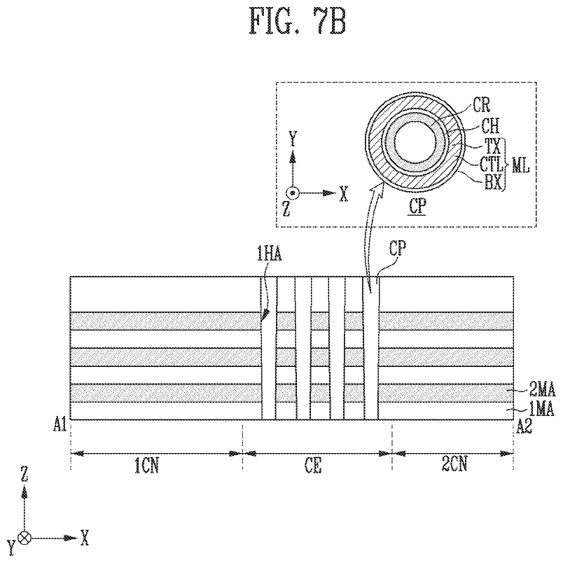

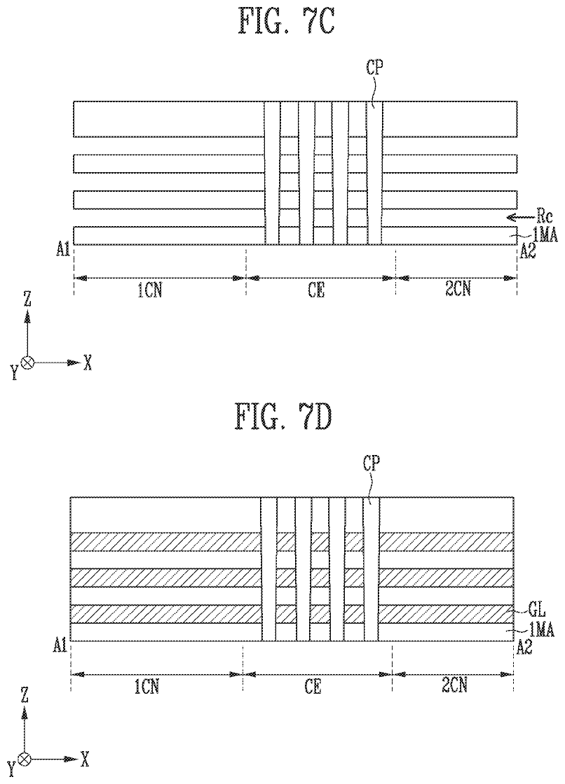

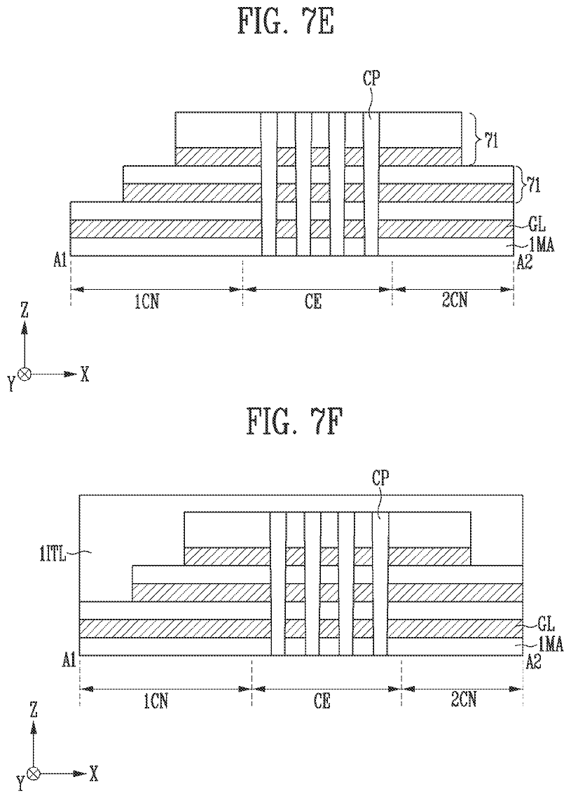

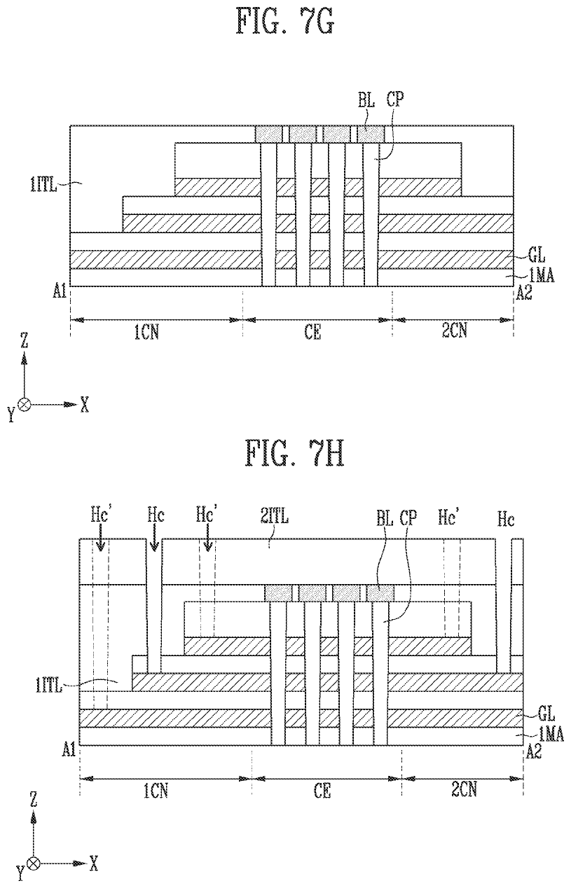

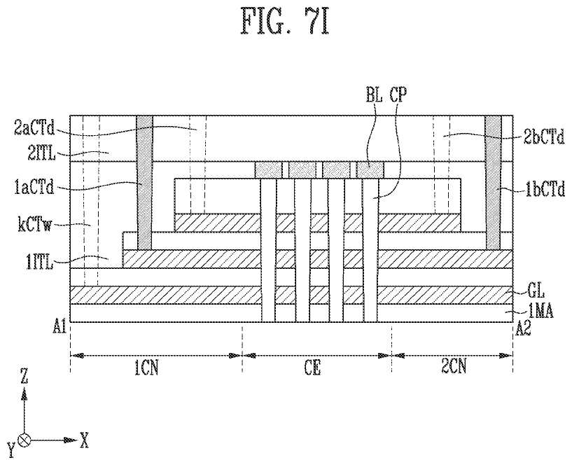

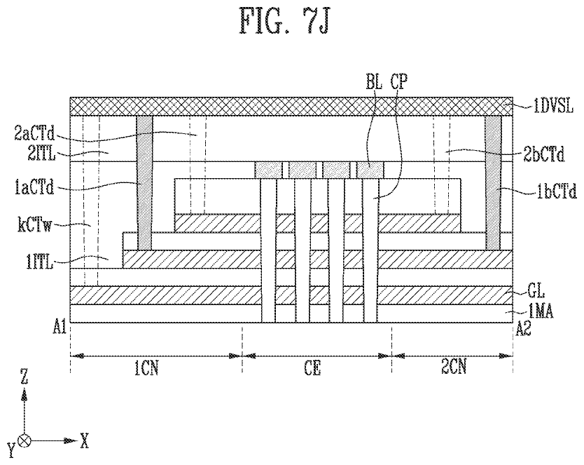

FIGS. 7A to 7J are diagrams illustrating a method of manufacturing the memory device according to the first embodiment of the present disclosure, and are cross-sectional views of the drawing shown in FIG. 6 taken along a A1-A2 direction.

Referring to FIG. 7A, a partial region including drain selection lines is shown in the memory block of the memory device. First and second material layers 1MA and 2MA may be alternately stacked. The number of the first and second material layers 1MA and 2MA is not limited to the number shown in the drawing. The first and second material layers 1MA and 2MA may be alternately stacked on a lower structure (not shown). The lower structure may be the peripheral circuit, the source line, or the substrate. The first material layer 1MA may be an insulating layer, and the second material layer 2MA may be a sacrificial layer. For example, the first material layer 1MA may be an oxide layer, and the second material layer 2MA may be a nitride layer. The first and second connection regions 1CN and 2CN divided along the X direction and the cell region CE may be designated in the first and second material layers 1MA and 2MA. The cell region CE may be positioned between the first and second connection regions 1CN and 2CN.

Referring to FIG. 7B, first holes 1HA extending in a vertical direction are formed in the first and second material layers 1MA and 2MA of the cell region CE, and the cell plugs CP may be formed in the first holes 1HA. A process for forming the first holes 1HA may be performed as an anisotropic etching process. Each of the cell plugs CP formed inside the first holes 1HA may include the core pillar CR, the channel layer CH, the tunnel insulating layer (tunnel isolation layer) TX, the charge trap layer CTL, and the blocking layer BX. The core pillar CR may have a cylindrical shape and may be formed of an insulating material or a conductive material. The channel layer CH may have a cylindrical shape surrounding a side surface of the core pillar CR, and may be formed of polysilicon. The tunnel insulating layer TX may have a cylindrical shape surrounding a side surface of the channel layer CH and may be formed of an oxide layer. The charge trap layer CTL may have a cylindrical shape surrounding a side surface of the tunnel insulating layer TX and may be formed of a nitride layer. The blocking layer BX may have a cylindrical shape surrounding a side surface of the charge trap layer CTL and may be formed of an oxide layer.

Referring to FIG. 7C, the slit SLT of FIG. 2 for dividing the memory blocks may be formed, and an etching process for removing the second material layers 2MA exposed through the slit may be performed. For example, an isotropic etching process may be performed. When the second material layers 2MA are removed, a recess Rc, which is an empty space, may be formed between the first material layers 1MA.

Referring to FIG. 7D, gate lines GL may be formed between the first material layers 1MA. The gate lines GL may be a conductive layer. For example, the conductive layer for the gate lines GL may be a metal material such as tungsten (W), molybdenum (Mo), cobalt (Co), nickel (Ni), or a semiconductor material such as silicon (Si) or poly-silicon (Poly-Si), but is not limited thereto. The gate lines GL may be a source selection line, a word line, or a drain selection line.

Referring to FIG. 7E, a step structure may be formed in the first and second connection regions 1CN and 2CN. The first material layer 1MA and the gate line GL contacting each other may form a pair, and a step structure may be formed in each pair. For example, each of steps may be formed in a structure in which the first material layer 1MA is positioned on the gate line GL, but in contrast, each of the steps may be formed in a structure in which the gate line GL is positioned on the first material layer 1MA. In the present embodiment, the structure in which the first material layer 1MA is positioned on the gate line GL is shown. Therefore, the first material layer 1MA may be exposed at each step.

In the first connection region 1CN, all pairs of the first material layers 1MA and gate lines GL may be formed in a step structure, in the second connection region 2CN, only pairs 71 including the gate lines GL designated as the drain selection line may be formed in a step structure, and pairs positioned thereunder may have a cross section cut in the Z direction.

Referring to FIG. 7F, a first interlayer insulating layer 1ITL may be formed on the entire structure including the step structure. The first interlayer insulating layer 1ITL may be an oxide layer. Because an upper surface of the first interlayer insulating layer 1ITL might not be flat due to a height difference between the cell region CE and the first and second connection regions 1CN and 2CN, after the first interlayer insulating layer 1ITL is formed, a planarization process for flatten the upper surface of the first interlayer insulating layer 1ITL may be performed.

Referring to FIG. 7G, openings exposing an upper surface of the cell plugs CP may be formed, and the bit lines BL may be formed in the openings. The bit lines BL may be a conductive layer. The bit lines BL may be spaced apart from each other in the X direction.

Referring to FIG. 7H, a second interlayer insulating layer 2ITL may be formed on the bit lines BL and the first interlayer insulating layer 1ITL. The second interlayer insulating layer 2ITL may be formed of the same material as the first interlayer insulating layer 1ITL. Subsequently, contact holes Hc exposing the gate line GL of each step may be formed in the first and second connection regions 1CN and 2CN. For example, in the first connection region 1CN, because the gate lines GL positioned on different layers form a step, contact holes Hc and HC′ exposing the gate lines GL may be formed at each step. In the second connection region 2CN, because only the gate lines GL designated as the drain selection line have a step structure, the contact holes Hc and HC′ may be formed on the gate lines GL having the step structure. In the second connection region 2CN, because the remaining gate lines GL positioned under the gate lines GL designated as the drain selection lines do not form a step structure, the contact holes Hc are not formed on the gate lines GL that do not form a step structure. Referring to FIGS. 6 and 7H, because the A1-A2 cross-section is a cross-section of a portion where the first drain voltage supply line 1DVSL extends, the contact holes Hc may be formed in a region where the 1a-th drain contact 1aCTd and the 1b-th drain contact 1bCTd are to be formed, and in a cross-section other than the A1-A2, the contact holes Hc′ exposing the gate lines GL included in different steps may be formed.

Referring to FIG. 7I, the 1a-th drain contact 1aCTd, the 1b-th drain contact 1bCTd, the 2a-th drain contact 2aCTd, the 2b-th drain contact 2bCTd, and the k-th word line contact kCTw may be formed by filling the contact holes Hc and Hc′ with a conductive material.

Referring to FIG. 7J, voltage supply lines may be formed on the 1a-th drain contact 1aCTd, the 1b-th drain contact 1bCTd, the 2a-th drain contact 2aCTd, the 2b-th drain contact 2bCTd, the k-th word line contact kCTw, and the second interlayer insulating layer 2ITL. For example, the first drain voltage supply line 1DVSL contacting the 1a-th drain contact 1aCTd and the 1b-th drain contact 1bCTd may be formed in the A1-A2 cross-section.

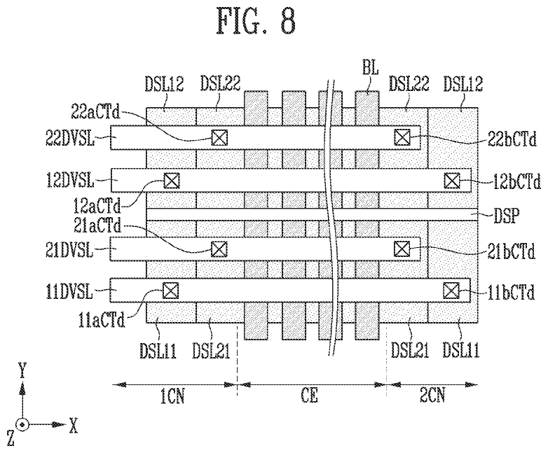

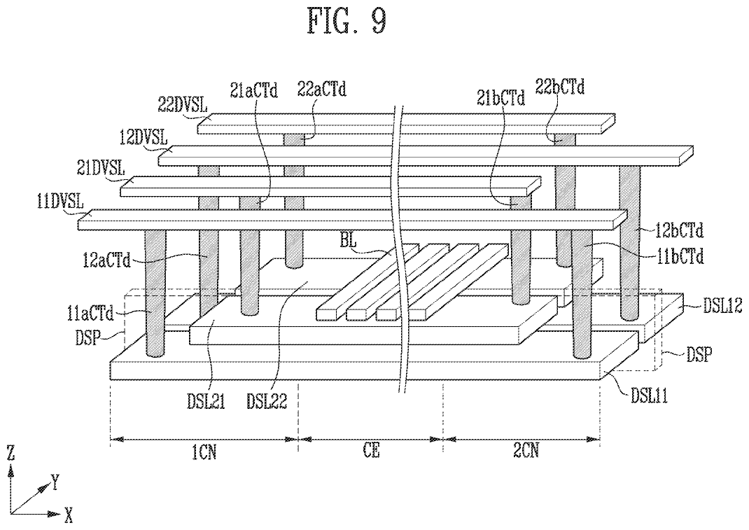

FIG. 8 is a layout diagram illustrating a structure of a memory device according to a second embodiment of the present disclosure, and FIG. 9 is a perspective view illustrating the structure of the memory device according to the second embodiment of the present disclosure.

Referring to FIGS. 8 and 9, the drain selection lines included in the same memory block may be separated by a drain separation pattern DSP. For example, the first drain selection line DSL1 of the first embodiment may be separated into eleventh and twelfth drain selection lines DSL11 and DSL12 in the second embodiment, and the second drain selection line DSL2 of the first embodiment may be separated into twenty-first and twenty-second drain selection lines DSL21 and DSL22 in the second embodiment. Because the drain separation pattern DSP extends along the X direction, the eleventh and twelfth drain selection lines DSL11 and DSL12 may be separated from each other along the Y direction, and the twenty-first and twenty-second drain selection lines DSL21 and DSL22 may also be separated from each other along the Y direction. The twenty-first drain selection line DSL21 may be positioned on the eleventh drain selection line DSL11, and the twenty-second drain selection line DSL22 may be positioned on the twelfth drain selection line DSL12.

An 11a-th drain contact 11aCTd may be positioned on the eleventh drain selection line DSL11 of the first connection region 1CN, and an 11b-th drain contact 11bCTd may be positioned on the eleventh drain selection line DSL11 of the second connection region 2CN. An eleventh drain voltage supply line 11DVSL may be positioned on the 11a-th drain contact 11aCTd and the 11b-th drain contact 11bCTd. Therefore, when the drain voltage is supplied to the eleventh drain voltage supply line 11DVSL, the drain voltage may be applied to both ends of the eleventh drain selection line DSL11 through the 11a-th drain contact 11aCTd and the 11b-th drain contact 11bCTd.

A 12a-th drain contact 12aCTd may be positioned on the twelfth drain selection line DSL12 of the first connection region 1CN, and a 12b-th drain contact 12bCTd may be positioned on the twelfth drain selection line DSL12 of the second connection region 2CN. A twelfth drain voltage supply line 12DVSL may be positioned on the 12a-th drain contact 12aCTd and the 12b-th drain contact 12bCTd. Therefore, when the drain voltage is supplied to the twelfth drain voltage supply line 12DVSL, the drain voltage may be applied to both ends of the twelfth drain selection line DSL12 through the 12a-th drain contact 12aCTd and the 12b-th drain contact 12bCTd.

A 21a-th drain contact 21aCTd may be positioned on the twenty-first drain selection line DSL21 of the first connection region 1CN, and a 21b drain contact 21bCTd may be positioned on the twenty-first drain selection line DSL21 of the second connection region 2CN. A twenty-first drain voltage supply line 21DVSL may be positioned on the 21a-th drain contact 21aCTd and the 21b-th drain contact 21bCTd. Therefore, when the drain voltage is supplied to the twenty-first drain voltage supply line 21DVSL, the drain voltage may be applied to both ends of the twenty-first drain selection line DSL21 through the 21a-th drain contact 21aCTd and the 21b-th drain contact 21bCTd.

A 22a-th drain contact 22aCTd may be positioned on the twenty-second drain selection line DSL22 of the first connection region 1CN, and a 22b-th drain contact 22bCTd may be positioned on the twenty-second drain selection line DSL22 of the second connection region 2CN. A twenty-second drain voltage supply line 22DVSL may be positioned on the 22a-th drain contact 22aCTd and the 22b-th drain contact 22bCTd. Therefore, when the drain voltage is supplied to the twenty-second drain voltage supply line 22DVSL, the drain voltage may be applied to both ends of the twenty-second drain selection line DSL22 through the 22a-th drain contact 22aCTd and the 22b-th drain contact 22bCTd.

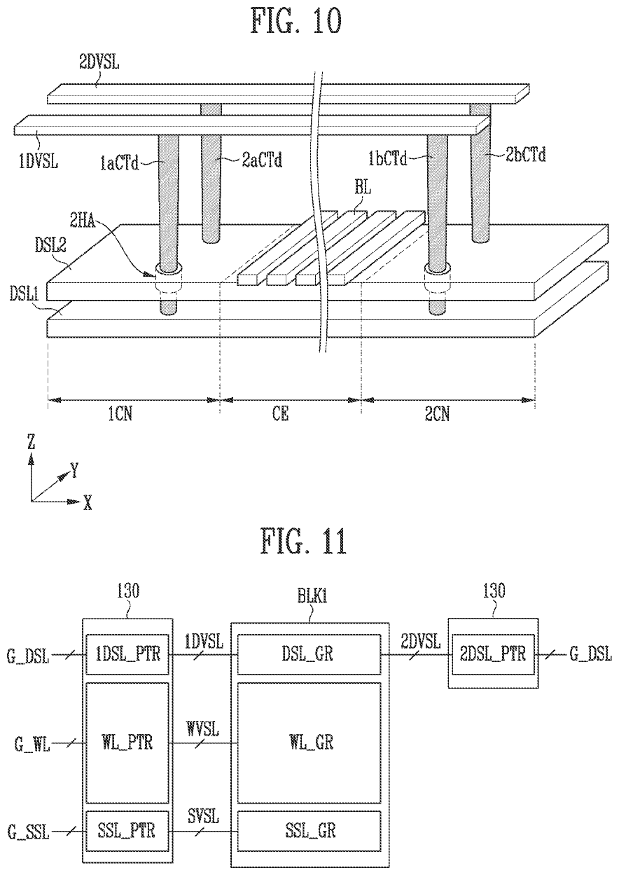

FIG. 10 is a perspective view illustrating a structure of a memory device according to a third embodiment of the present disclosure.

Referring to FIG. 10, the first and second drain selection lines DSL1 and DSL2 might not have a step structure and may be formed in a stack structure having the same length (a length of the X direction) in the first and second connection regions 1CN and 2CN. Although not shown in the drawings, word lines and source lines positioned under the first drain selection line DSL1 may also be formed in a stack structure having the same length (a length of the X direction) without being formed in a step structure.

As described in the first or second embodiment, in the third embodiment, the 1a-th drain contact 1aCTd may be connected to the first connection region 1CN of the first drain voltage supply line 1DVSL, and the 1b-th drain contact 1bCTd may be connected to the second connection region 2CN of the drain voltage supply line 1DVSL. Because the 1a-th drain contact 1aCTd and the 1b-th drain contact 1bCTd are required to contact the first drain selection line DSL1, second holes 2HA may be formed in a portion of the second drain selection line DSL2. The second holes 2HA may be formed in a region where the 1a-th drain contact 1aCTd and the 1b-th drain contact 1bCTd pass through, and may have a width wider than a width of the 1a-th drain contact 1aCTd and the 1b-th drain contact 1bCTd. An insulating layer may be formed between an inner wall of the second holes 2HA and the 1a-th drain contact 1aCTd and the 1b-th drain contact 1bCTd to electrically block the 1a-th drain contact 1aCTd and the 1b-th drain contact 1bCTd from the second drain selection line DSL2.

The 2a-th drain contact 2aCTd may be connected to the first connection region 1CN of the second drain voltage supply line 2DVSL, and the 2b-th drain contact 2bCTd may be connected to the second connection region 2CN of the second drain voltage supply line 2DVSL. The 2a-th drain contact 2aCTd may contact the first connection region 1CN of the second drain selection line DSL2, and the 2b-th drain contact 2bCTd may contact the second connection region 2CN of the second drain selection line DSL2.

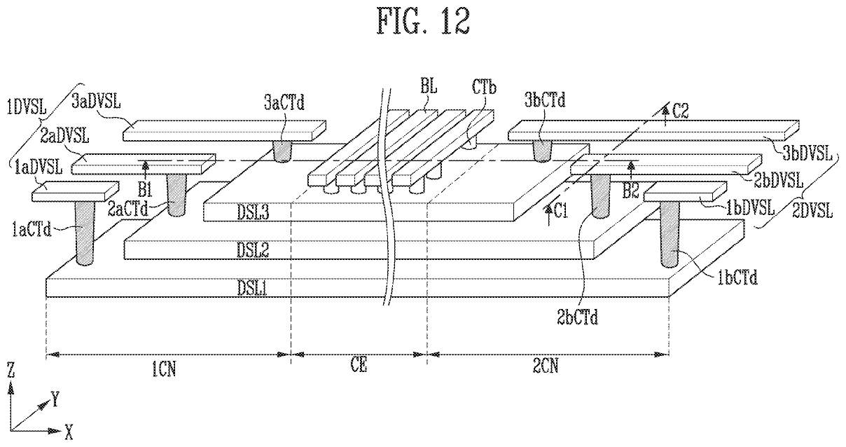

FIG. 11 is a circuit diagram illustrating a connection structure of a memory device according to a fourth embodiment of the present disclosure.

Referring to FIG. 11, drain selection lines included in a drain selection line group DSL_GR may be divided into two groups, and drain selection lines included in each of two groups may be connected to the first drain voltage supply lines 1DVSL or the second drain voltage supply lines 2DVSL. When describing the first memory block BLK1 as an example, the first memory block BLK1 may include the drain selection line group DSL_GR, a word line group WL_GR, and a source selection line group SSL_GR. The drain selection line group DSL_GR may include the drain selection lines connected to the drain selection transistors. The word line group WL_GR may include the word lines connected to the memory cells. The source selection line group SSL_GR may include the source selection lines connected to the source selection transistors. The row decoder 130 may include first and second drain selection line pass transistors 1DSL_PTP and 2DSL_PTP, word line pass transistors WL_PTR, and source selection line pass transistors SSL_PTR.

The first and second drain selection line pass transistors 1DSL_PTP and 2DSL_PTR may be commonly connected to a global drain selection lines G_DSL. The first drain selection line pass transistors 1DSL_PTP may transfer the drain voltage to the first drain voltage supply lines 1DVSL, and the second drain selection line pass transistors 2DSL_PTP may transfer the drain voltage to the second drain voltage supply lines 2DVSL. The drain voltage transferred to the first and second drain voltage supply lines 1DVSL and 2DVSL may be simultaneously supplied to the drain selection lines included in the drain selection line group DSL_GR. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The word line pass transistors WL_PTR may be commonly connected to global word lines G_WL. The word line pass transistors WL_PTP may transfer the word line voltage to the word line voltage supply lines WVSL. The word line voltage transferred to the word line voltage supply lines WVSL may be supplied to the word lines included in the word line group WL_GR.

The source selection line pass transistors SSL_PTP may be commonly connected to global source selection lines G_SSL. The source selection line pass transistors SSL_PTP may transfer the source voltage to the source voltage supply lines SVSL. The source voltage transferred to the source voltage supply lines SVSL may be simultaneously supplied to the source selection lines included in the source selection line group SSL_GR.

FIG. 12 is a perspective view illustrating the structure of the memory device according to the fourth embodiment of the present disclosure.

Referring to FIG. 12, the first drain voltage supply lines 1DVSL and the second drain voltage supply lines 2DVSL may be positioned on the same layer as the bit lines BL. That is, lower surfaces of the first drain voltage supply lines 1DVSL, the second drain voltage supply lines 2DVSL, and the bit lines BL may be positioned on the same XY plane.

A structure of each of regions is described in detail as follows.

First to third drain selection lines DSL1 to DSL3 may be sequentially stacked. For example, the second drain selection line DSL2 may be positioned on the first drain selection line DSL1, and the third drain selection line DSL3 may be positioned on the second drain selection line DSL2. A length of the second drain selection line DSL2 in the X direction is shorter than a length of the first drain selection line DSL1 in the X direction, and a length of the third drain selection line DSL3 in the X direction is shorter than the length of the second drain selection line DSL2 in the X direction. Therefore, an upper surface of each of the first to third drain selection lines DSL1 to DSL3 may be exposed in the first and second connection connections 1CN and 2CN.

Cell plugs (not shown) passing through the first to third drain selection lines DLS1 to DSL3 may be positioned in the cell region CE, and bit line contacts CTb may contact the cell plugs. Because the cell plugs are the same as the cell plugs CP of FIG. 5 shown in FIG. 5, a repetitive description is omitted. The bit lines BL may be arranged on the bit line contacts CTb. The bit lines BL may extend along the Y direction and may be spaced apart along the X direction. The bit lines BL may be positioned on the same plane. For example, the bit lines BL may be positioned on a plane where the first and second drain voltage supply lines 1DVSL and 2DVSL are positioned.

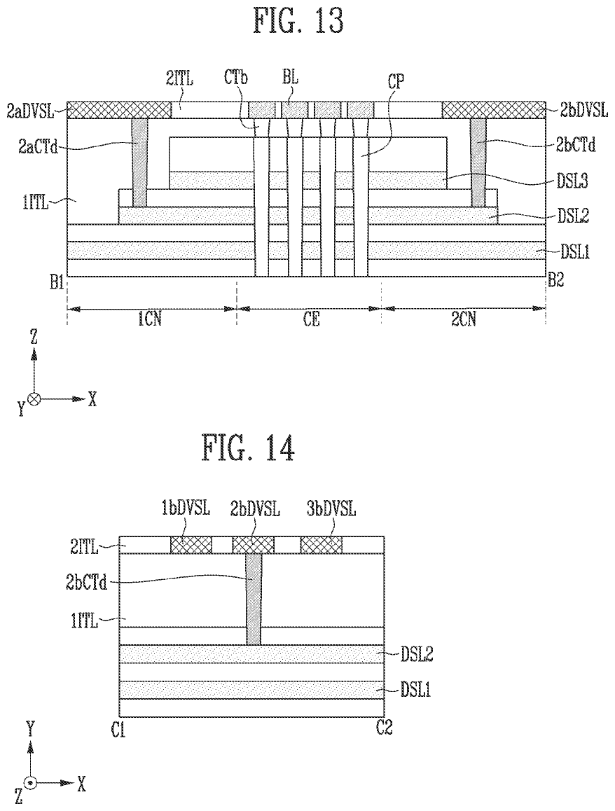

FIG. 13 is a view illustrating a B1-B2 cross-section of the structure shown in FIG. 12, and FIG. 14 is a view illustrating a C1-C2 cross-section of the structure shown in FIG. 12.

Referring to FIGS. 13 and 14, the B1-B2 cross-section shows the 2a-th and 2b-th drain voltage supply lines 2aDVSL and 2bDVSL and the bit lines BL, and the C1-C2 cross-section shows the 1b-th, 2b-th, and 3b-th drain voltage supply lines 1bDVSL, 2bDVSL, and 3bDVSL.

The 2a-th and 2b-th drain contacts 2aCTd and 2bCTd may be positioned on the second drain selection line DSL2 exposed to the first and second connection regions 1CN and 2CN. For example, the 2a-th and 2b-th drain contacts 2aCTd and 2bCTd may pass through the first interlayer insulating layer 1ITL to contact the second drain selection line DSL2. The 2a-th drain voltage supply line 2aDVSL may be positioned on the 2a-th drain contact 2aCTd, and the 2b-th drain voltage supply line 2bDVSL may be positioned on the 2b-th drain contact 2bCTd.

The second interlayer insulating layer 2ITL may be filled between the 2a-th drain voltage supply line 2aDVSL, the 2b-th drain voltage supply line 2bDVSL, and the bit lines BL. Therefore, lower surfaces of the 2a-th drain voltage supply line 2aDVSL, the 2b-th drain voltage supply line 2bDVSL, and the bit lines BL may be positioned on the same plane as a boundary surface between the first and second interlayer insulating layers 1ITL and 2ITL. A thickness of the 2a-th drain voltage supply line 2aDVSL and the 2b-th drain voltage supply line 2bDVSL may be equal to or different from a thickness of the bit lines BL.

The 1b-th, 2b-th, and 3b-th drain voltage supply lines 1bDVSL, 2bDVSL, and 3bDVSL contacting different drain selection lines, respectively, may be positioned on the same plane on the first interlayer insulating layer 1ITL.

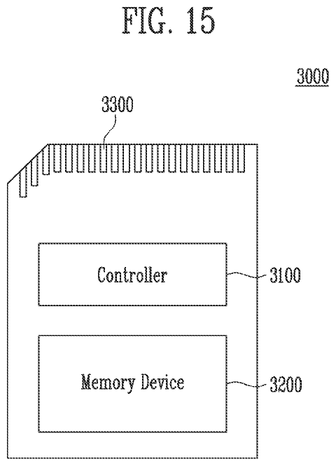

FIG. 15 is a diagram illustrating a memory card system to which a memory device of the present disclosure is applied.

Referring to FIG. 15, the memory card system 3000 includes a controller 3100, a memory device 3200, and a connector 3300.

The controller 3100 is connected to the memory device 3200. The controller 3100 is configured to access the memory device 3200. For example, the controller 3100 may be configured to control a program, read, or erase operation of the memory device 3200 or to control a background operation. The controller 3100 is configured to provide an interface between the memory device 3200 and a host. The controller 3100 is configured to drive firmware for controlling the memory device 3200. For example, the controller 3100 may include components such as a random access memory (RAM), a processing unit, a host interface, a memory interface, and an error correction circuit.

The controller 3100 may communicate with an external device through the connector 3300. The controller 3100 may communicate with an external device (for example, the host) according to a specific communication standard. For example, the controller 3100 is configured to communicate with an external device through at least one of various communication standards such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 3300 may be defined by at least one of the various communication standards described above.

The memory device 3200 may include a plurality of memory cells, and may be configured identically to the memory device 100 shown in FIG. 1.

The controller 3100 and the memory device 3200 may be integrated into one semiconductor device to configure a memory card. For example, the controller 3100 and the memory device 3200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

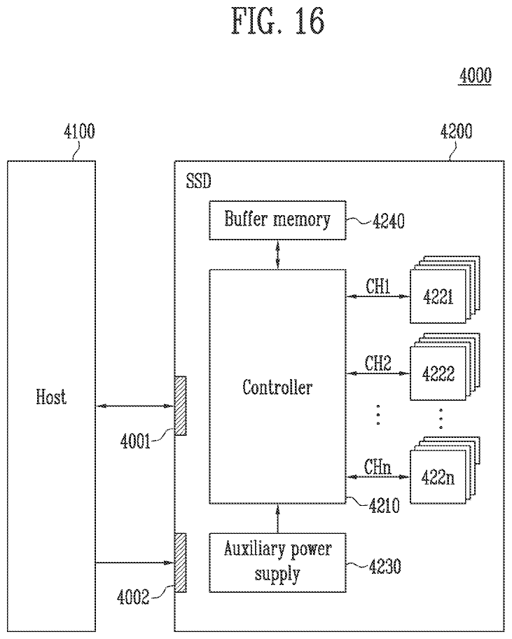

FIG. 16 is a diagram illustrating a solid state drive (SSD) system to which a memory device of the present disclosure is applied.

Referring to FIG. 16, the SSD system 4000 includes a host 4100 and an SSD 4200. The SSD 4200 exchanges a signal with the host 4100 through a signal connector 4001 and receives power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to the signal received from the host 4100. For example, the signal may be signals based on an interface between the host 4100 and the SSD 4200. For example, the signal may be a signal defined by at least one of interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 is connected to the host 4100 through the power connector 4002. The auxiliary power supply 4230 may receive a power voltage from the host 4100 and charge the power voltage. The auxiliary power supply 4230 may provide a power voltage of the SSD 4200 when power supply from the host 4100 is not smooth. For example, the auxiliary power supply 4230 may be positioned in the SSD 4200 or may be positioned outside the SSD 4200. For example, the auxiliary power supply 4230 may be positioned on a main board and may provide auxiliary power to the SSD 4200.

The buffer memory 4240 operates as a buffer memory of the SSD 4200. For example, the buffer memory 4240 may store data received from the host 4100 or data received from the plurality of memory devices 4221 to 422n, or may store meta data (for example, a mapping table) of the memory devices 4221 to 422n. The buffer memory 4240 may include a volatile memory such as a DRAM, an SDRAM, a DDR SDRAM, and an LPDDR SDRAM, or a nonvolatile memory such as an FRAM, a ReRAM, an STT-MRAM, and a PRAM.

What is claimed is:

1. A memory device comprising:
a memory block in which first and second connection regions and a cell region between the first and second connection regions are designated;
a word line included in the memory block;
a first drain selection line included in the memory block and positioned on the word line;
a first drain contact contacting the first drain selection line of the first connection region;
a second drain contact contacting the first drain selection line of the second connection region; and
a first drain voltage supply line commonly contacting the first and second drain contacts.

2. The memory device of claim 1, further comprising:
a peripheral circuit positioned under the memory block.

3. The memory device of claim 1, further comprising:
a cell plug positioned between a bit line and a source line in the cell region of the memory block.

4. The memory device of claim 3, wherein the cell plug comprises:
a first drain selection transistor contacting the first drain selection line; and
a memory cell contacting the word line.

5. The memory device of claim 3, wherein the bit line is positioned between the first drain voltage supply line and the first drain selection line.

6. The memory device of claim 3, wherein the first drain selection transistor is configured to be turned on or turned off in response to a voltage applied from the first and second connection regions of the first drain selection line.

7. The memory device of claim 1, further comprising:
a second drain selection line positioned on the first drain selection line;
a third drain contact contacting the second drain selection line of the first connection region;
a fourth drain contact contacting the second drain selection line of the second connection region; and
a second drain voltage supply line commonly contacting the third and fourth drain contacts.

8. The memory device of claim 7, wherein in the first and second connection regions, the first and second drain selection lines have a step structure in which upper surfaces are exposed, respectively.

9. The memory device of claim 8, wherein the first and second drain contacts are spaced apart from the second drain selection line.

10. The memory device of claim 7, wherein in the first and second connection regions, only an upper surface of the second drain selection line of the first and second drain selection lines is exposed.

11. The memory device of claim 10, wherein the second dummy selection line includes holes through which the third and fourth drain contacts pass.

12. The memory device of claim 11, wherein in the holes, the third and fourth drain contacts are spaced apart from an inner wall of the holes.

13. The memory device of claim 1, further comprising:
a third drain selection line positioned on the same layer as the first drain selection line;
a drain separation pattern electrically separating between the first and third drain selection lines;
a fifth drain contact contacting the third drain selection line of the first connection region;
a sixth drain contact contacting the third drain selection line of the second connection region; and
a third drain voltage supply line commonly contacting the fifth and sixth drain contacts.

14. A memory device comprising:
first and second connection regions and a cell region between the first and second connection regions;
a first drain selection line extended in a first direction to be located within the first and second connection regions and the cell region;
a bit line positioned on the first drain selection line in the cell region;
a first drain contact contacting the first drain selection line of the first connection region;
a second drain contact contacting the first drain selection line of the second connection region;
a first drain voltage supply line contacting the first drain contact; and
a second drain voltage supply line contacting the second drain contact,
wherein the first and second drain voltage supply lines and the bit line are positioned on the same plane.

15. The memory device of claim 14, further comprising:
a second drain selection line positioned between the first drain selection line and the bit line;
a third drain contact contacting the second drain selection line of the first connection region;
a fourth drain contact contacting the second drain selection line of the second connection region;
a third drain voltage supply line contacting the third drain contact; and
a fourth drain voltage supply line contacting the fourth drain contact,
wherein the first to fourth drain voltage supply lines and the bit line are disposed on the same plane.

16. A memory device comprising:
a voltage generator configured to output a drain voltage through a global line;
a row decoder connected to the voltage generator through the global line and transferring the drain voltage to a drain voltage supply line;
a drain selection line connected to a memory block; and
drain contacts connected to both ends of the drain selection line,
wherein the drain contacts are commonly connected to the drain voltage supply line.
